(19) United States
(12) Patent Application Publication
(10) Pub. No.: US 2014/0041714 A1
(43) Pub. Date: Feb. 13, 2014

(54) SOLAR CELL LAMINATE COMPRISING CRYSTALLINE SILICON PHOTO-ELECTRICITY DEVICE AND PROCESS TO MAKE SUCH A LAMINATE

(71) Applicant: Lennert Frans Van Den Berg, Geldermalsen (NL)

(72) Inventor: Lennert Frans Van Den Berg, Geldermalsen (NL)

(73) Assignee: FLEXSOL SOLUTIONS B.V., Delft (NL)

(21) Appl. No.: 13/985,389

(22) PCT Filed: Feb. 13, 2012
(86) PCT No.: PCT/NL2012/050077

§ 371 Date: Oct. 28, 2013

(30) Foreign Application Priority Data
Feb. 15, 2011 (NL) 2006202

(51) Int. Cl. H01L 31/0203; H01L 31/048; H01L 31/18

(52) U.S. Cl. CPC H01L 31/0203; H01L 31/18; H01L 31/0481; H01L 31/0482
USPC 136/251; 438/93; 136/259

(57) ABSTRACT

The invention is directed to a solar cell laminate comprising crystalline silicon photo-electricity device and comprising of the following layers: (i) a first layer comprising of a woven or knit glass mat and a thermoset polymer, (ii) a second layer comprising a crystalline silicon photo-electricity device, and (iii) a third layer comprising of a woven or knit fibre mat and a thermoset polymer.

The invention relates to a solar cell laminate comprising crystalline silicon photo-electricity device. The invention also relates to a process of making a solar cell laminate comprising crystalline silicon photo-electricity device and applications of such a solar cell laminate.

Crystalline silicon photo-electricity devices are well known for their high efficiency to convert sunlight into electricity. The crystalline silicon used in the typical devices is extremely vulnerable. For this reason these devices are typically protected by a layer of glass. For some applications it is desirable to be able to obtain the crystalline silicon device in a curved shape. For most curved shape applications thin film solar cells are used. Because these thin film solar cells have a lower efficiency than crystalline silicon based cells to generate electricity it is for some applications desirable to use the crystalline silicon in a curved shape.

Various technologies have been proposed to obtain a crystalline silicon device in a curved shape. For example in EP2071635 a process is described to make a curved crystalline solar cell wherein a back-contacted cell is first packed in a deformable ethylene-vinyl-acetate (EVA) cover and support layer. Subsequently the packed solar cell is deformed such that the crystalline silicon breaks into fragments wherein the fragments remain contacted at the breaks.

EP2068375 describes a solar cell laminate comprising crystalline silicon photo-electricity device wherein the silicon sheet is embedded in a cross-linked polymer layer. The solar cell laminate is flexible to a certain extent.

The object of the present invention is to obtain a solar cell laminate which is more flexible that the prior art solar cell laminate.

This object is achieved by the following solar cell laminate. A solar cell laminate comprising crystalline silicon photo-electricity device and comprising of the following layers:
(i) a first layer comprising of a woven or knit glass mat and a polymer,
(ii) a second layer comprising a crystalline silicon photo-electricity device, and
(iii) a third layer comprising of a woven or knit fibre mat and a polymer.

The invention is also directed to the following process to make a solar cell laminate. Process to make a solar cell laminate wherein the solar cell laminate comprises of a cover layer comprised of a fluorocarbon-based polymer, a first layer comprising of a woven or knit glass mat and a polymer, a second layer comprising a crystalline silicon photo-electricity device, and a third layer comprising of a woven or knit glass mat and a polymer by
(a) placing a film of the fluorocarbon-based polymer on a support to create a cover layer,
(b) placing the first, second and third layer on top of the cover layer to obtain a layered intermediate,
(b) creating a vacuum around the layered intermediate,
(c) increasing the temperature of the layered intermediate to a temperature not exceeding by 50° C. the glass transition temperature of the polymer of the first layer,
(d) cooling the layered intermediate and
(e) releasing the vacuum to obtain the solar cell laminate.

Applicants found that the laminate according to the invention has a much higher flexibility that the prior art laminate comprising a crystalline silicon photo-electricity device. This is advantageous because it makes the laminate more robust and also applicable on very curved surfaces, such as street light poles. Other advantages will be described below. Another advantage is that a very light weight and robust solar cell based on a crystalline silicon photo-electricity device is obtained when compared to the state of the art products having a glass cover. This allows easy transport of the laminate and products comprising said laminate making it very suited for use in remote areas, for example for camping use.

The first layer (i) comprises of a woven or knit glass mat and a polymer. The polymer is preferably a thermoset polymer but may alternatively also be a thermoplastic polymer. The thermoset polymer may be a polyester, a polyurethane or an epoxy resin. More preferably epoxy resins are used, suitably epoxy resins based on diglycidyl ethers of bisphenol A are used. Preferably the thermoset polymer should be transparent. Preferably the thermoset polymer has a glass transition temperature which is higher than the temperature the laminate may reach when exposed to the sun. Preferably the glass transition temperature is greater than 80° C., more preferably greater than 100° C. and even more preferably greater than 125° C.

The woven or knit glass mat suitably has a density of between 10 and 200 g/m² (gsm) and more preferably between 10 and 80 g/m² and even more preferably between 20 and 80 g/m². Preferably a woven glass mat is used. Preferably one layer of glass mat is present in the first layer (i). More layers of glass mat may be present, but applicant found that the advantageous bending properties can be achieved with one layer and that more layers of glass mat will only lower the transparency of the first layer which is not desired from an energy efficiency standpoint. The thickness of the first layer is between 40 and 200 μm.

The glass mat and the thermoset polymer are preferably combined as a so-called pre-preg. The pre-preg comprises of the thermoset polymer precursor and a curing agent. When the temperature is increased the thermoset polymer precursor compounds undergo a cross-linking reaction thereby forming the thermoset polymer material. The pre-peg may comprise of so-called unidirectional glass fibres. In order to achieve good bending properties in all directions of the laminate multiple pre-pegs of unidirectional glass fibres are suitably applied in combination wherein the direction of the glass fibres of one pre-peg is different from the other pre-preg. Suitably the direction is about 90° relative to each other. A suited pre-preg is an epoxy-woven glass mat as can be obtained from Advanced Composite Group Ltd.

The second layer comprises a crystalline silicon photo-electricity device. The crystalline silicon photo-electricity device is capable of converting solar radiation into direct current electricity. This device suitably comprises a sheet of mono or poly crystalline silicon. This also includes the so-called heterogeneous devices which are composed of a single thin crystalline silicon wafer sandwiched by ultra-thin amorphous silicon layers of which the HIT*1 Solar Cell of Sanyo Electric Co. Ltd is an example. The devices are preferably of the so-called backside contact solar cells as for example described in U.S. Pat. No. 7,633,006. These devices are well known and can be obtained from companies like SunPower Corporation of San Jose, Calif. (US) or the Sunweb product of Solland Solar Cells BV using the so-called metal wrapped through (MTW) technique.

The third layer comprises of a woven or knit fibre mat and a polymer. The polymer is preferably a thermoset polymer as described for the first layer but may alternatively also be a thermoplastic polymer. The polymer used in the first layer may be the same or different from the polymer used in the third layer and preferably the same. Preferably a woven fibre mat is used. The fibres are suitably non-conductive and examples of suitable fibres are aramid, polyethylene, for example Dyneema, polypropylene and natural fibres such as flax. A preferred fibre is glass. In an even more preferred embodiment the same woven or knit glass mat and thermoset polymer as used for the first layer is used as third layer, wherein the weight of the glass mat in said third layer may be higher than for the glass mat used in the first layer. The weight of the glass mat in the third layer may be between 10 and 200 g/m² and suitably between 20 and 200 g/m². Using the same components for said first and third layer is advantageous because it reduces stress between said layers when manufacturing said laminate. In this third layer the transparency is not critical as no sunlight has to pass through this layer on its way to the crystalline silicon photo-electricity device. The thickness of the third layer is between 40 and 200 μm.

The solar cell laminate as described above is preferably protected by one or more cover layers at the side through which sunlight has to pass. Furthermore the solar cell laminate may be combined with one or more support layers at the opposite side.

The cover layer is preferably made of a material which has a good weather ability, corrosion resistance, high refractive index, high impact strength and water-repellency. Preferably the cover layer is a film of a fluorocarbon-based polymer. Fluorocarbon-based polymers are advantageous because they meet the desired properties and because they remain transparent and do not yellow or become clouded after prolonged exposure to sunlight. Examples of suited fluorocarbon-based polymers are those described as protective layer for thin film solar cells as for example described in EP641030 and in EP755080. Examples of suitable fluorocarbon-based polymers are ETFE (ethylene-tetrafluoroethylene copolymer) as for example obtainable from DuPont as Tefzel and ECTFE (ethylene chlorotrifluoroethylene) as for example obtainable from Solvay as Halar and FEP (fluorinated ethylene propylene) as obtainable from DuPont.

The thickness of the cover layer is preferably between 20 and 200 μm and more preferably between 30 and 100 μm. The cover layer preferably comprises an UV blocker and/or an appropriate hindered amine light stabiliser. The UV blocker compound can be a commercially available UV absorber, for example salicylic acid series compounds, benzophenone series compounds, benzotriazole series compounds, and cyanoacrylate series compounds. The use of such UV blockers and light stabilisers in protective films for thin film solar cells is known and these compositions can also be used as UV blocker in the cover layer of the laminate according to the present invention. See for example the earlier referred to in EP641030 and in EP755080. A texture or surface treatment can be applied to the cover layer to increase sunlight absorption.

The support layer may also be a metal film, like for example an aluminium film, or a fibre reinforced polymer, wherein the fibres are for example glass, aramid and carbon fibres or polymers like for example polyvinyl fluoride films, like Tedlar® as obtainable from DuPont or Polyvinylidene fluoride (PVDF), a combination of PVF or PVDF with PET, Polyamide, ETFE, ETCFE, Fluorcopolymer or Aluminium as can be found in several ICOSOLAR products as obtained from ISOVOLTAIC and AKASOL products as obtainable from the Krempel Group. The fibres may be arranged in said polymer as non-woven, woven or knit. The polymer may be a thermoset or thermoplastic, like for example ethylene-vinyl-acetate (EVA). The support layer may be a structural element of another apparatus, like for example the deck of a boat, the wing or fuselage of an aeroplane or airship or the roof of an automobile.

A connection layer may be connected to the third or optional support layer. This connection layer, which may have a roughened surface, will improve adhesion of the laminate to other surfaces. The third layer or the support layer may also be modified to enhance connection. The surface properties of said layers may be enhanced for example for the adhesion for gluing by using well-known peel ply surface modification methods. Alternatively the third or optional support layer may be connected to another layer of the fluorocarbon-based polymer as described for the cover layer. In this manner a sealed off laminate is obtained which can be used as such or fixed to, e.g. by mechanical means, like screws, bolts or ties, to another object or surface.

The cover, first and third layer suitably have a larger dimension than the crystalline silicon photo-electricity device. This ensures that the crystalline silicon photo-electricity device is sufficiently encapsulated by these layers and thus protected against weather and the like. The laminate as described above having a first, second and third layer may have a thickness of between 200 and 700 μm.

The solar cell laminate having an optional cover layer composed of a film of a fluorocarbon-based polymer as described above and optionally a support layer and/or an optional second film of a fluorocarbon-based polymer at its opposite side can be used as such as a solar cell or be combined with well known protection layers which are known to protect solar cells for a prolonged period of time. A possible laminate can be composed of a layer of ETFE, a layer of EVA, the laminate according the invention comprised of the first, second and third layer, a layer of EVA supported by a layer of Tedlar®. The combination of EFTE, EVA and Tedlar® has a good weatherability.

The invention is also directed to a process to make a solar cell laminate wherein the solar cell laminate comprises of a cover layer comprised of a fluorocarbon-based polymer, a first layer comprising of a woven or knit glass mat and a polymer, preferably a thermoset polymer, a second layer comprising a crystalline silicon photo-electricity device, and a third layer comprising of a woven or knit fibre mat and a polymer, preferably a thermoset polymer. This process is especially directed to make a solar laminate as described above according to the present invention.

In this process, in a step (a), a film of the fluorocarbon-based polymer is placed on a support to create a cover layer. The support, also referred to as tooling surface, may be a glass plate. The surface of the glass plate may be provided with a texture resulting in that the final surface of the cover layer will be less reflective. The fluorocarbon-based polymer is suitably a polymer described above. The surface facing the first layer of said polymer film is preferably subjected to a surface treatment, such as for example a corona treatment, plasma treatment, ozone treatment, irradiation with UV rays, irradiation with electron rays, flame treatment, etching or provided with a coating in order to improve the adhesion properties of this film. This treatment is preferably performed prior to performing step (a) or prior to step (b).

In step (b) the first, second and third layer is positioned on top of the cover layer to obtained a layered intermediate. The light sensitive side of the crystalline silicon photo-electricity device should face the first layer. After creating a vacuum the temperature of the layered intermediate is suitably increased in step (c) to a temperature not exceeding the glass transition temperature by 50° C. of the thermoset polymer of the first and or third layer and suitably not exceeding the glass transition temperature by 30° C. of the thermoset polymer of the first and/or third layer, whichever temperature is the lowest. More preferably the temperature of the layered intermediate is increased in step (c) to a temperature range of between 20 and 0° C. below the glass transition temperature of the thermoset polymer of the first layer. Subsequently the layered intermediate is cooled in a step (d) and in a step (e) the vacuum is released to obtain the solar cell laminate. The conditions applied in steps (a) to (e) may be those as generally known to the skilled person in the field of manufacturing photovoltaic modules.

The invention is also directed to a support and the solar laminate according to the invention as described above or obtainable by the process of as described above wherein the solar laminate is present on the, preferably curved, surface of the object. Examples of such objects are roof tiles, building facades, urban and non-urban street furnishing, for example road signs, soundproofing road barriers, advertising boards and signs, lamp posts, shelters, garden lights, ships, automobiles, airplanes, airships, tents and backpacks.

A preferred object is an inflatable object having a curved surface provided with the solar laminate according to the invention on said curved surface. The inflatable object is advantageous because it can be easily transported to a location of use. At the location it can be inflated and positioned, for example at sea, near the end user of the generated electricity. Because the solar laminate is flexible it will not be damaged when transported and inflated. The invention is also directed to a floating solar park comprising numerous of such inflatable objects anchored to the seabed and connected to shore to transport electricity as generated by the floating solar park. The solar cells of the floating solar park may also be other flexible solar cells, such as of the thin film type. Thus the invention is directed to a solar park comprising more than one floating and inflatable objects provided at its surface with a solar cell. Preferably the solar cell is comprised in a solar cell laminate according to the invention or obtainable according to the process according to the invention. Such solar parks are advantageous because they can be readily installed at the shores of remote locations. This is especially advantageous in case of a natural disaster wherein sunlight may provide part of the necessary power.

Another preferred object is a tubular formed object comprising one or more solar laminates as described above. More preferably the tubular formed object has an outer layer of glass. The tubular glass layer may be fully covered by solar cells around its circumferential or partly. Such tubular objects with a glass outer layer can be advantageously be used as part of the support poles of devices requiring electricity, such as street lights, traffic lights, advertisement boards and art works. The tubular objects may also be used as part of the poles of wind turbines wherein the electricity generated by the solar cells can be easily added to the electricity generated by the wind turbine. The objects provided with the tubular formed objects are advantageous over the known object, such as street lighting, which use flat solar panels in that they are less vulnerable to heavy wind forces, snow cover, bird droppings and/or leaves. Furthermore applicants found that the solar efficiency of the tubular formed solar cells is greater or the same as compared to a flat solar cell having the same surface area.

Such a tubular formed object can be made by applying a single bag vacuum cure process and more preferably by applying a double vacuum cure process. In the vacuum cure process the solar laminate as described above are placed against the inside of a tube. The solar laminate is suitably already cured to avoid the crystalline solar cell to break when applied to the curved surface. Prior to curing in the above single or double bag vacuum process adjacent layers may entrap air pockets in between. Additionally, volatiles, as released during the curing process, solvents and humidity may remain entrapped in the layers. By using the single and the even more preferred double vacuum process a void-free laminate can be obtained. In the double vacuum process the difference in pressure at both sides of the vacuum bag is less than in the single bag vacuum process. This will result in that less force will be exerted by the vacuum bag on the laminate layers, thereby allowing air and other volatiles to more easily move through said layers to the point where they will be discharged from the laminate by means of the applied vacuum.

The invention is thus directed to a double vacuum process wherein the cured solar laminate as sandwiched between two layers of a polymer is placed against the interior of a tube, covering the resulting layers in a gas tight manner with a vacuum bag wherein the ends of the vacuum bag are sealed to the interior of the tube and applying a vacuum to the centre of the tube and a vacuum to the space between the vacuum bag and the interior wall of the tube at an elevated temperature to achieve curing of the polymer.

This process provides a simple method of applying a double vacuum to tubular structures, in which the tubular structure itself is used as vacuum chamber. The process can also be used for producing any kind of curved and in particular tubular laminates for reducing the amount of voids (air and volatiles) entrapped in the laminate and to increase the mechanical properties of the layup. It can be used for producing curved and tubular objects and also be used for bonding a laminate or structure to the interior of a tube for manufacturing of hybrid tubes. Thus the process of applying a double vacuum bag process to make a curved laminate may be used to make a curved solar laminate according to the present invention. In addition the invention is directed to the more general process of making a curved laminate, wherein the laminate may be every laminate which requires a curing and a double bag vacuum process. Examples of suitable laminates are solar laminates in general, wherein the solar cell may be of the film type, crystalline type or amorphous type and wherein the crystalline type solar cell laminates are preferably the solar cell laminates according to the present invention described above. Other applications of this process wherein the tube becomes part of the end product is wherein the laminate comprises an image and wherein this image is fixed to the interior of a transparent, suitably glass tube, by the present process; or where the laminate is a reinforcement layer applied to the interior of a glass or metal tube by the present process; or where the laminate is a polymer used to coat the interior of a metal tube by the present process; or where the laminate comprises a metal sheet applied to the interior of a glass tube by the present process; or where the laminate is a combination of a fibre reinforced polymer and a metal sheet applied to the interior of a tube, for example a glass, metal or polymer tube.

The invention is thus also directed to a process to make a curved laminate by placing one or more films of a polymer on the interior of a tube, covering the one or more films in a gas tight manner with a vacuum bag wherein the ends of the vacuum bag are sealed to the interior of the tube and applying a vacuum to the centre of the tube and a vacuum to the space between the vacuum bag and the interior wall of the tube at an elevated temperature to achieve curing of the polymer. Instead of a tube, in principle any pipe type design may be used having for example an oval cross-section, square, rectangular, provided it has at least one open end to be able to place the one or more films of polymer. The interior wall does not necessarily have to be of the same shape as the outer wall of the pipe. To cope with the vacuum pressure applied to the device it is preferred to have at least a tubular outer wall or enough wall thickness.

The obtained tubular object as obtained by the above process may be cut in parts if so desired. For example it may be cut in a perpendicular direction relative to its longitudinal axis to obtain parts of a tube or in the direction of the axis to obtain curved objects. For example such curved objects provided with a solar cell may be used as roof tiles or may be applied to curved surfaces of building facades.

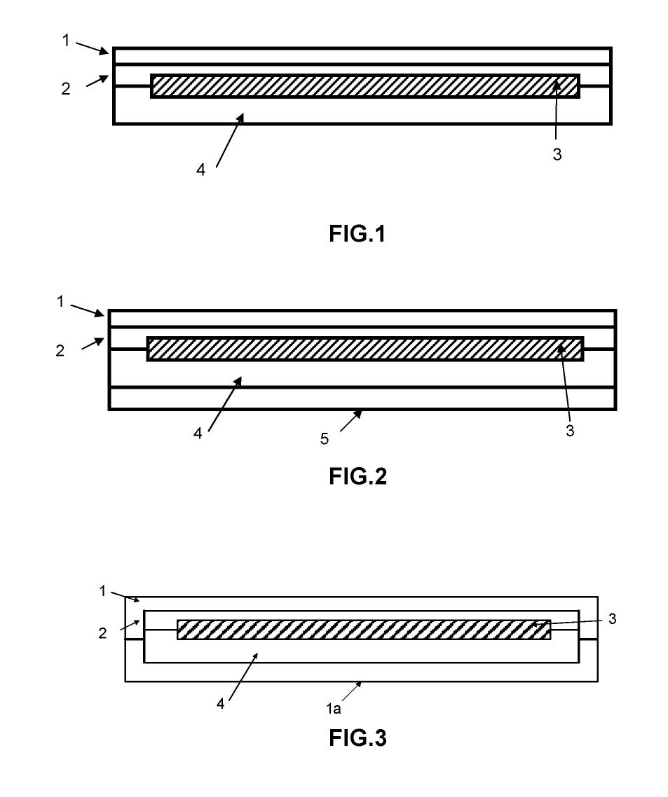

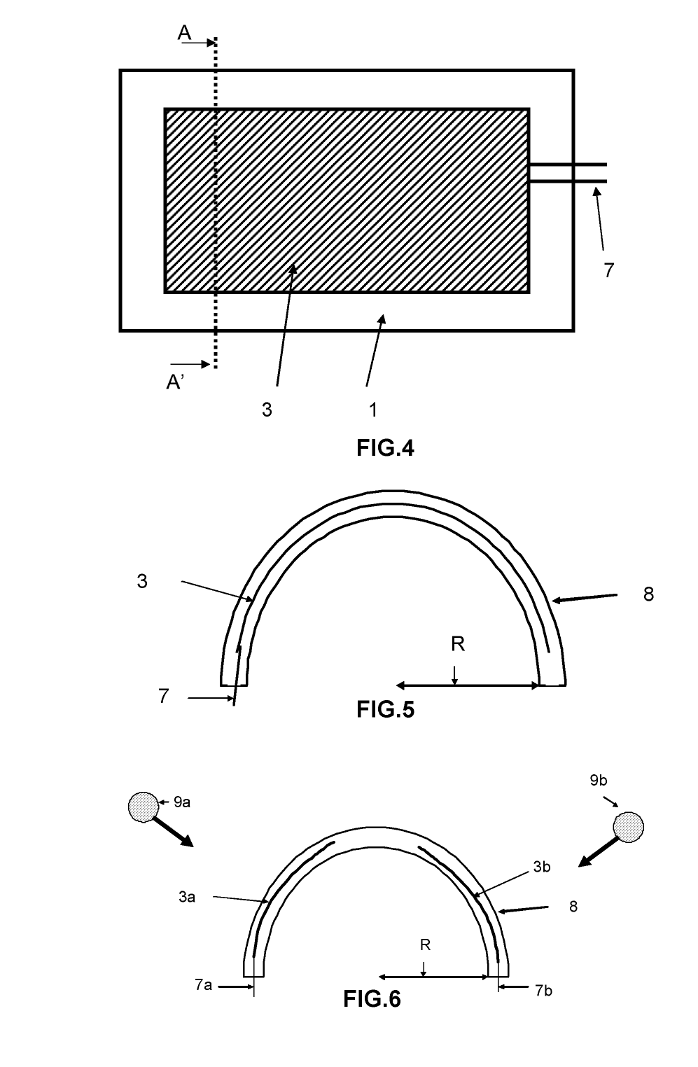

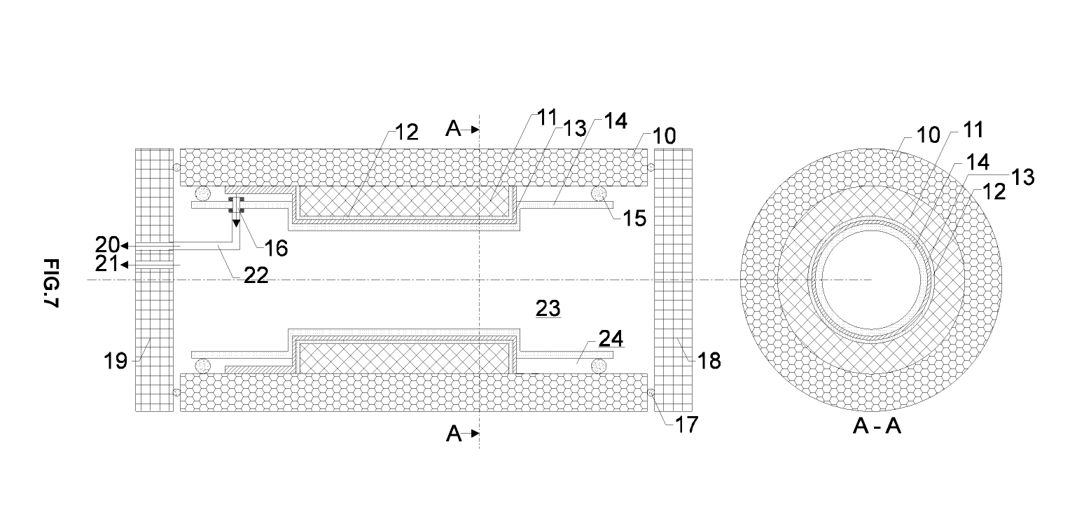

In this process the tooling surface is the interior surface of the tube. By using the interior surface of the tube as the tooling surface it is possible to avoid having to use the additional vacuum chamber of the prior art process as shown in FIGS. 3 and 4 of U.S. Pat. No. 7,186,367 and FIG. 1-7 of WO 2011/075252. Instead it is preferred to place two end caps in a gas tight manner on both open ends of the tube. The resulting assembly is furthermore provided with openings to apply the necessary vacuum to the main interior space of the tube and an opening to the space between vacuum bag and the interior wall to apply a vacuum to the laminate as present in said space. This entire assembly can be simply subjected to a heat source such to achieve the necessary elevated temperature for the curing process, suitably by placing the assembly in an oven.

In one embodiment of this process a release film or agent is present between the one or more films of a polymer and the interior wall of the tube. In this embodiment the tube is removed from the curved laminate after curing. An example of a suited release film is Wrightlon 4500 or Wrightlon 5200 as obtained by Airtech. An example of a suited release agent is Marbocote® 227 as obtained by Marbocote or Chemlease® PMR as obtained by Chemtrend

At the interior of the one or more films in the tube a so-called bleeder/breather is suitably placed before placing the vacuum bag. The bleeder will enhance the degassing of the laminate once the vacuum is applied. Between the bleeder and the laminate a permeable, perforated or porous release film may be present. An example of a permeable perforated or porous release film is Wrightlon 3900 or Wrightlon 3700 as obtained by Airtech.

In another embodiment the tube is a glass tube and the glass tube is not removed from the curved laminate after curing such to obtain a curved laminate with a glass outer layer.

The laminate as applied at the interior may comprise an image. The layers radially outward of the image are preferably transparent. The outer layer may be a glass layer and preferably a glass tube used in the above process.

Preferably the curved laminate comprises a solar cell comprised of a mono crystalline silicon solar cell elements, polycrystalline silicon solar cell elements, amorphous silicon solar cell elements, copper-indium-selenide solar cell elements and compound semiconductor solar cell elements. In case the solar cell is less susceptible for breakage, like in case of thin film solar cells the cells and the polymer layers enveloping the solar cell may be cured in one step using the process described above involving the tube. In case of solar cells which are susceptible of breakage it is preferred to first make a solar laminate as described above and apply said cured solar cell laminate to the interior of the tube.

The laminate and preferably the above referred to cured laminate comprising a solar cell is preferably sandwiched by a further layer of polymer. In this preferred process the tube is a glass tube and a radial outer layer of a transparent polymer, a layer of the cured solar laminate and a next layer of a polymer is used. The radial outer layer is preferably composed of ethylene vinyl acetate (EVA). The next layer may also be composed of EVA. Polyvinyl butyral (PVB) or thermoplastic polyurethane (TPU) can also be used for the radial outer layer and the next layer.

The double vacuum bag process itself can be performed in a similar manner as known for performing a double bag vacuum process using a flat tooling plate as described in the afore mentioned U.S. Pat. No. 7,186,367 or WO2011/075252, which references are hereby incorporated by reference. In the present process the layers as described above are applied to the interior surface of the tube. The layers are subsequently enclosed by a vacuum bag. The vacuum bag is preferably a tubular formed bag. After inserting the bag into the tube the ends are sealed at the ends of the tube. Via an opening fluidly connecting the exterior and the space between vacuum bag and the interior of the tube a first vacuum is applied. Via another opening fluidly connecting the exterior of the tube and the centre of the tube a second vacuum is applied. For curing, this assembly of tube, layers and vacuum bag is placed inside an oven and subjected to a cure cycle. The oven preferably has a forced air circulation.

The cure cycle may be as known for prior art double bag vacuum processes. In such a cycle the difference in vacuum pressure between the first vacuum and the second vacuum may be gradually increased in time. It is further preferred that the temperature is gradually increased to a maximum temperature and then gradually decreased, preferably to ambient temperature, while the vacuum is maintained throughout the cure cycle. At the start of the cure cycle the pressure at both sides of the vacuum bag is the same or almost the same. In this way the layers are not severely compacted by the applied vacuum pressure, such that the layers remains loose and air and volatiles are free to escape by the vacuum suction of the first vacuum. By gradually increasing the pressure of the second vacuum in the centre of the tube at the elevated temperature the layers will be further cured to obtain the end product. The pressure of the second vacuum can be increased to even atmospheric pressure.

A preferred pressure level for the first vacuum as applied to the space between the vacuum bag and the interior wall of the tube is between 0 and 300 mbar and more preferably between 0 and 50 mbar. The pressure level of the second vacuum as applied to the centre of the tube may range from 0 to 1030 mbar. Preferably this pressure is maintained at a lower pressure of between 0 and 300 mbar, more preferably between 0 and 50 mbar at the start of the curing cycle and increases during the curing cycle to a level of between 400 and 1030 mbar. It is preferred that the pressure of the second vacuum is equal or higher that the pressure of the first vacuum.

The elevated temperature during curing may range from 80 to 200° C. and will depend on the minimum cross-linking temperature of the used polymer or polymers. Preferably the temperature is gradually increased from a low temperature, for example an ambient temperature to the above described temperature as quickly as possible, for example at a rate of between 0.5 and 10° C./min. When the curing temperature is reached it is preferably maintained at that temperature for a time ranging from 5 to 60 minutes. Preferably 15 to 60 minutes. After that period the temperature is allowed to decrease, for example by cooling against ambient air to a temperature of suitably below 50 ° C.

The invention is also directed to a tubular tooling device which may be advantageously be used in the process described above. The tubular tooling device may be a tube which is suitably part of the final object to be prepared or a reusable tooling tube which is removed from the curved laminate object.

The preferred tooling device is comprised of a tube, having an interior wall and gas-tight closed at both ends by means of an end cap, wherein at least one end cap is removable and wherein one opening is present fluidly connecting the exterior of the tubular tooling device with the centre space of the tubular tooling device and one opening is present fluidly connecting the exterior with a space adjacent to the interior wall of the tubular tooling device. The end caps suitably have a sidewall corresponding with the interior of the tubular tooling device such that they can be fitted into the open ends of the tubular tooling device. Preferably a seal is present between end cap or end caps and tooling device to achieve a gas tight connection between these parts when the vacuum is applied. The interior wall of the tubular tooling device may have a tubular design or may alternatively have any design, for example a design comprising both flat parts and curved parts. Suitably both end caps are removable to have better access to the interior of the tube when applying the different layers and the vacuum bag.

Suitably the opening fluidly connecting the centre of the tubular tooling device is present in one of the end caps. The opening fluidly connecting a space adjacent to the interior wall of the tubular tooling device may be present in the wall of the tubular tooling device or in one of the end caps. The two openings described above are in use connected to a device or devices able to apply a vacuum to the centre of the tooling device and to the space enclosed by the vacuum bag and the interior wall of the tooling device.

The tube of the tubular tooling device may be manufactured from any kind of material, for example steel, aluminium, glass, plastic and composites. The tube wall should have sufficient strength to avoid the tube to implode while applying the vacuum at the elevated temperatures.

FIG. 1 illustrates a cross-sectional view AA′ of FIG. 4 of a solar cell laminate according to the present invention, wherein a fluorocarbon-based polymer layer (1) is positioned on top of a first layer (2) comprising of a woven glass mat and a thermoset polymer. FIG. 1 also shows a third layer (4) comprising of a woven glass mat and a thermoset polymer. Sandwiched between layer (2) and (4) a crystalline silicon photo-electricity device (3) is positioned. In the embodiment shown in FIG. 1 the dimensions of the fluorocarbon-based polymer layer (1), the first layer (2) and the third layer (4) is larger dimension than the crystalline silicon photo-electricity device (3).

FIG. 2 illustrates a cross-sectional of a solar cell laminate as in FIG. 1 wherein an additional support layer (5) is added below layer (4). The reference numbers have the same meaning as in FIG. 1.

FIG. 3 illustrates a cross-sectional of a solar cell laminate as in FIG. 1 wherein an additional layer (1a) is added made from the same fluorocarbon-based polymer of layer (1). The dimensions of layer (1) and (1a) are larger than the first layer (2), the third layer (4) and the crystalline silicon photo-electricity device (3) to ensure that the crystalline silicon photo-electricity device (3) is sufficiently protected against weather and the like from all sides of the laminate.

FIG. 4 is a top view of the solar cell laminate of either FIG. 1, 2 or 3. Because fluorocarbon-based polymer layer (1) and layer (2) are transparent for sunlight crystalline silicon photo-electricity device (3) is visible. FIG. 4 also shows that the crystalline silicon photo-electricity device (3) is coupled by means of metal of pair of metal contacts (7) to the exterior of the laminate to allow an external electrical circuit or device to be coupled to and be powered by the crystalline silicon photo-electricity device (3). These metal contacts (7), at one side connected to the device (3), are preferably present between the first and third layer and extend at its opposite side from the laminate. The metal contacts may extend at the same side from the laminate as shown in FIG. 4 or alternatively one contact of the pair of contacts may extend at one side and the other at the opposite side of the solar laminate. One solar laminate may comprise one or more the crystalline silicon photo-electricity devices (3) wherein each device (3) will be individually connected to a pair of metal contacts (7) or connected in series within the laminate itself. Thus if more devices (3) are comprised in the solar cell laminate an equal number of pairs of contact devices (7) may extend from the laminate. Preferably the pair(s) of contact devices (7) are sandwiched between layer (2) and (4) using an additional glue-film.

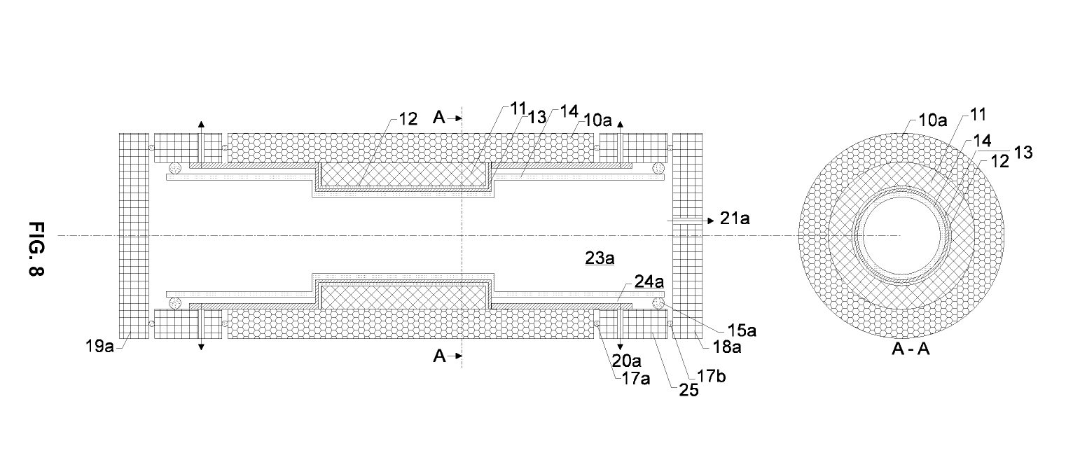

FIG. 5 shows the solar cell laminate (8) according to any one of FIG. 1 or 2 when bended at 180°. The radius R defines the bend of the solar cell laminate (8). Applicants found that the solar cell laminate according to the invention can be bend without damage to the cell at lower values for R than state of the art solar cell laminates comprising a crystalline silicon photo-electricity devices.

FIG. 6 shows a solar cell laminate (8) having two crystalline silicon photo-electricity devices (3a) and (3b) each connected to a pair of metal contacts (7a) and (7b) respectively. This is advantageous because when the sun (9a) shines predominately on the side of device (3a) the power generation by device (3a) will be greater than the power generated by device (3b) which receives less sunlight. Because the total power generated, by devices which are connected in series is limited by the weakest device in the chain it is preferred to have separate connections for every device or series of devices with the same alignment (e.g. inclination) to the sun. In this manner the power output is improved.

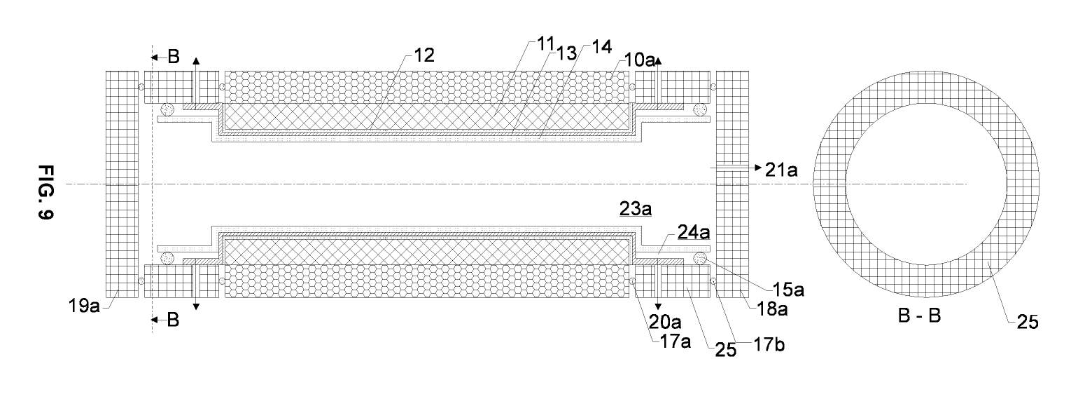

FIG. 7 shows a tubular tooling device 10 provided with two removable end caps 18, 19. End caps 18,19 are connected to tooling device 10 via a seal 17. At the interior wall of the tubular tooling device 10, a layer 11 is shown. Layer 11 may be a stack of layers as described above, for example the cured solar laminate enveloped by two layers of EVA. At the interior side of layer 11 a permeable, perforated or porous release film 12 and a bleeder\breather 13 is present. The total of layer 11, release film 12 and bleeder 13 is enclosed by a vacuum bag 14. Tubular vacuum bag 14 is sealed at its edges by sealing 15. Sealing 15 encloses the edges of the tubular vacuum bag to the interior of the tubular tooling device. Opening 21 as present in end cap 19 fluidly connects the centre space 23 of the tubular tooling device 10 with the exterior of the tooling device 10. Via said opening 21 the second vacuum can be applied. Opening 20 as present in end cap 19 fluidly connects the space between the vacuum bag 14 and the interior wall of tooling device 10 with the exterior of the tooling device via conduit 22 and a part 16. Via said opening 20 and conduit 22 the first vacuum can be applied to space 24.

Tooling device 10 can also be used to apply a single vacuum. In this embodiment the end caps are not required and only a first vacuum is applied via conduit 22.

FIG. 7 shows a view along its axis and a cross-sectional view AA. The dimensions of the different elements in FIG. 7 may be different and are drawn out of proportion in order to more clearly show the various elements.

FIG. 8 is a tooling device 10a provided with two removable end caps 19a and 18a. The tooling device 10a is connected to end caps 18a and 19a via rings 25, also referred to as tooling rings. Ring 25 is provided with an opening 20a connecting the space between the vacuum bag 14 and the tooling device 10a, called space 24a. Ring 25 provided with opening 20a is advantageous because it is easier to connect the first vacuum to this space. Ring 25 is connected to tooling device 10a via a seal 17a. As in FIG. 7, FIG. 8 shows a layer 11, a release film 12 and a bleeder 13. It is preferred to let the bleeder 13 cover opening or openings 20a. This will enhance a more uniform suction when the first vacuum is applied. Ring 25 is further connected to end cap 18 by sealing 17b. The vacuum bag 14 is preferably larger along the axis of the tooling device such that it can be sealed onto rings 25 by means of seals 15a. After this seal 15a is applied, the end caps 18a and 19a are placed and second vacuum may be applied via opening 21a to the centre space 23a of the tooling device 10a. Part 10a may be a glass tube. Because the end cap 18a and ring 25 are made of two separate parts it has been found easier to apply the different layers.

FIG. 8 shows a view along its axis and a cross-sectional view AA of the tooling device 10a. The dimensions of the different elements in FIG. 8 may be different and are drawn out of proportion in order to more clearly show the various elements.

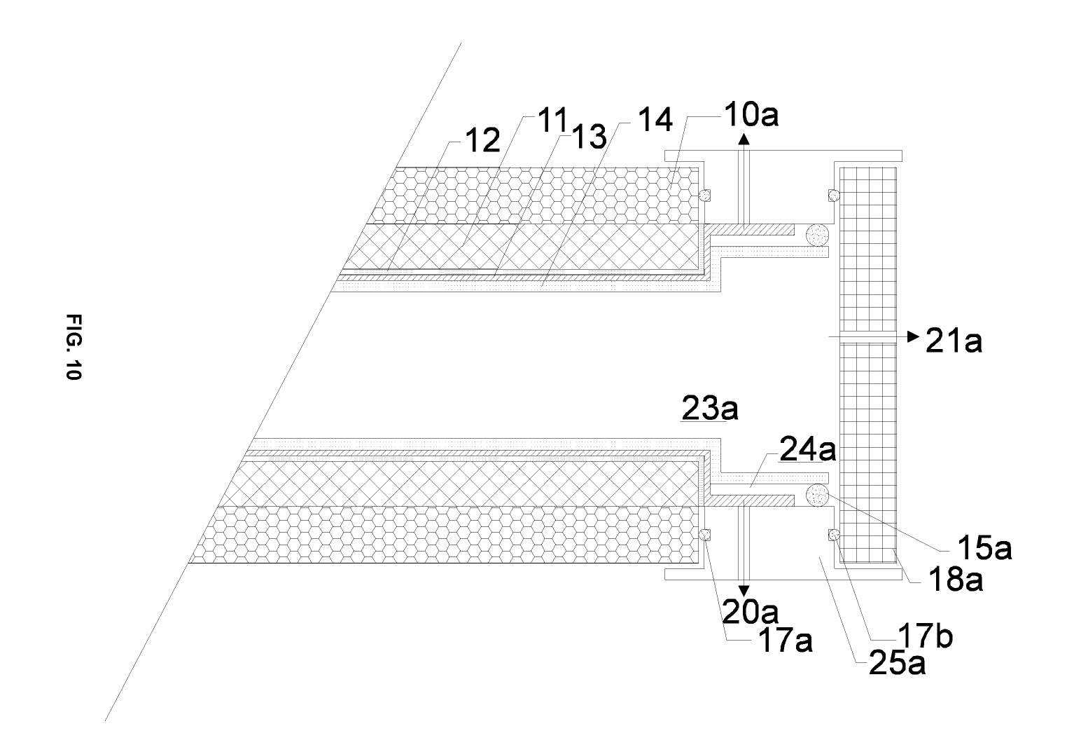

FIG. 9 shows a variant of the tooling device of FIG. 8 in that layer 11 is applied along the entire length of the tube part 10a.

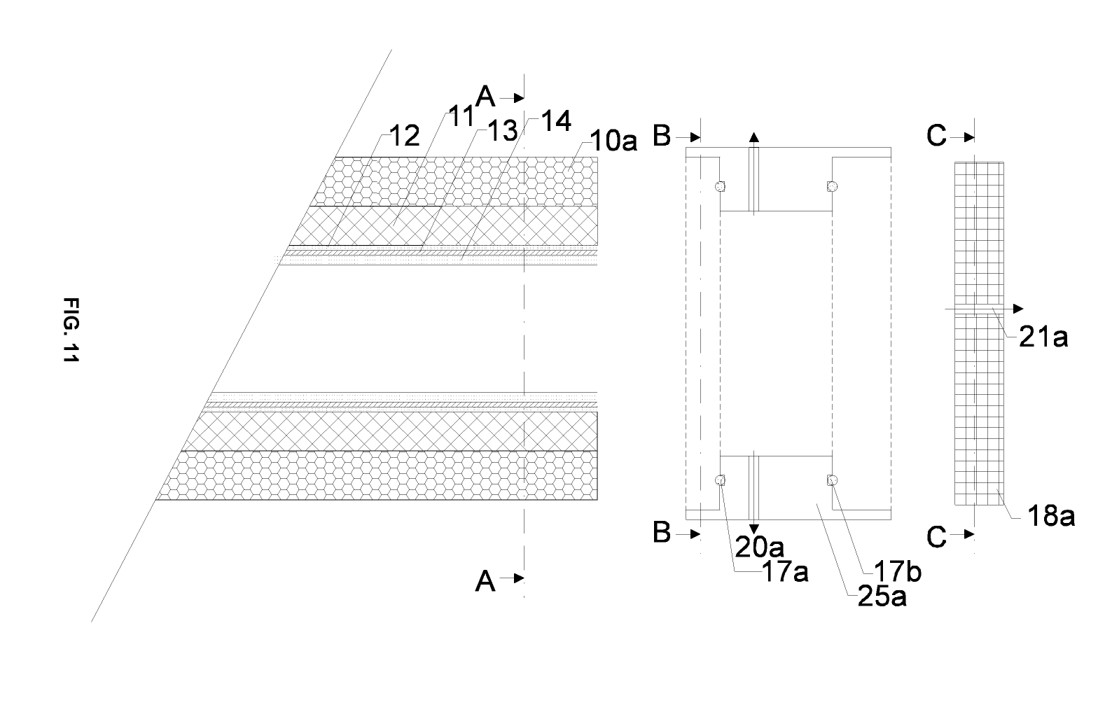

FIG. 10 is a detailed view of one of the ends of the double vacuum system of FIG. 9. The ring 25 of FIG. 9 is modified for a better assembly of the system; the tube part 10a and blind flange 18a will fall into the ring 25a. Extrusions are applied at the positions of the seals 17a and 17b, to keep the seals 17a and 17b better in position.

FIG. 11 shows the replaceable ring 25a and end cap 18a of the tooling device of FIG. 10 as separate parts.

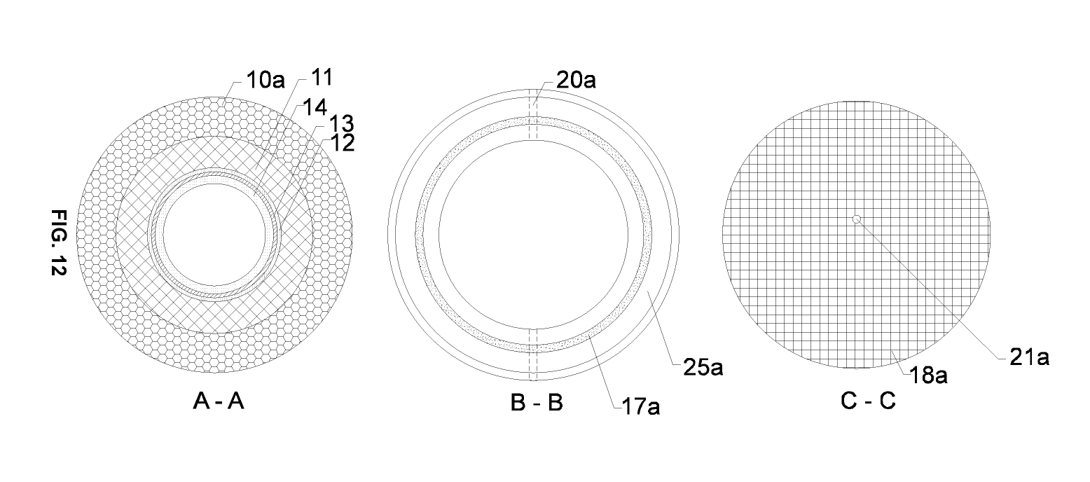

FIG. 12 shows three cross sectional views of FIG. 11. View A-A shows the cross sectional view of the layup of materials in the tube part 10a. View B-B shows the cross sectional view of the ring 25a. Ring 25a is suitably a metal ring. Because metal ring 25a will expand at the elevated temperatures of the curing the design should be such that this is possible without damaging for example the glass tube 10a as shown in FIG. 10. Through the ring 25a one or more openings 20a may be present to apply the first vacuum. The circular seal 17a of FIG. 11 is shown at the interface between tube 10a and ring 25a. View C-C shows the cross sectional view of the end cap 18a which may also be referred to as a blind flange. The blind flange may be a thick metal plate, which can handle the vacuum 23 applied to the blind flange 18a. In the blind flange opening 21a is shown.

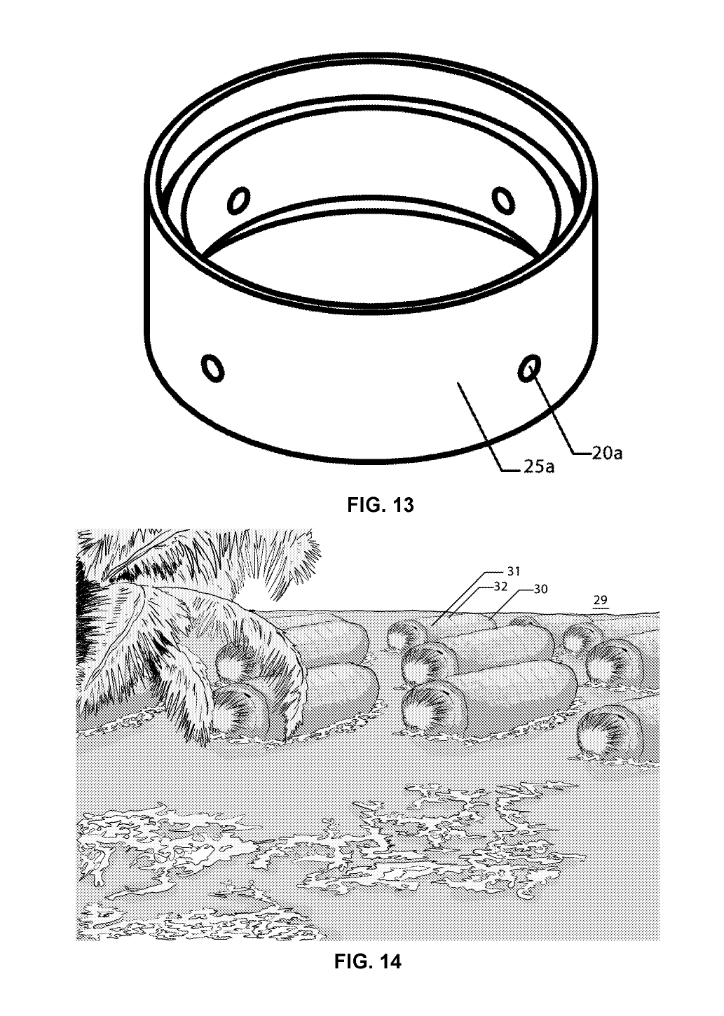

FIG. 13 shows a 3D view of ring 25a of FIG. 11.

FIG. 14 shows an artist impression as seen from the shore of a floating solar park 29 consisting out of more than one inflatable objects 30, provided with a solar laminate 31 according to the invention on said curved surface 32, and are anchored to the seabed.

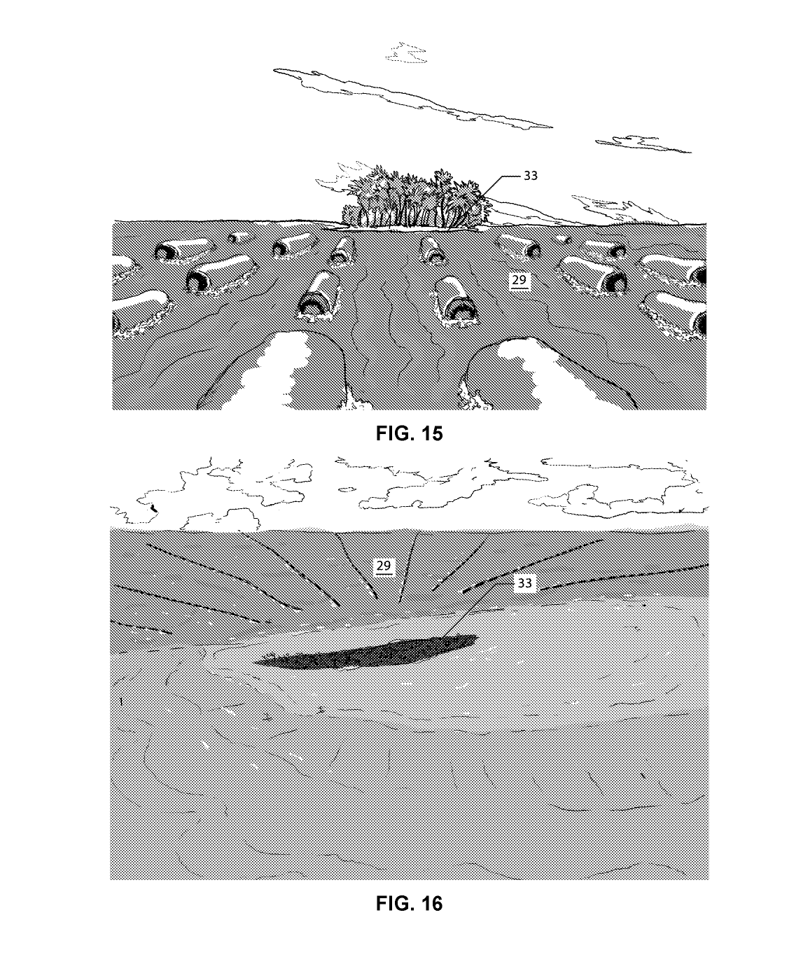

FIG. 15 shows an artist impression as seen from sea of floating solar park 29 positioned near the shore of an island 33.

FIG. 16 shows a bird-view artist impression of floating solar park 29 as positioned in a radial manner along the coast of island 33.

The invention will be illustrated by the following examples.

### EXAMPLE 1

On a glass tooling surface a sheet of Halar as obtained from Solvay Solexis (an ethylene chlorotrifluoroethylene (ECTFE)) of 100 μm was placed. On top of the sheet of Halar a sheet of a 23 grams/m² glass fibre pre-preg (Cycom®759F 70% A1100/23gsm glass fibre) was placed. The thermoset polymer of the pre-preg had a glass transition temperature of >135° C. A SunPower A300 solar cell (the crystalline silicon photo-electricity device) was placed with its light sensitive side facing downwards. A next sheet of a 23 grams/m² glass fibre pre-preg (Cycom®759F 70% A1100/23gsm glass fibre) was placed on top.

After placing a release film followed by a bleeder/breather and vacuum bag a vacuum was applied of 5 mbar and the laminate was allowed to de-air for 4 hours. Subsequently the temperature is raised to 100° C. and the laminate is cured for 4 hours. Subsequently the laminate is allowed to cool to room temperature. At room temperature the vacuum is released and the solar laminate is obtained having the dimensions of 12 by 12 cm of crystalline silicon photo-electricity device in a 14 by 14 cm laminate. The thickness of the laminate is between 300 and 600 μm.

The solar cell laminate as obtained was bended to 180°. The minimum radium R (FIG. 5) at which no breakage of the cell occurred was found to be 6 cm.

### EXAMPLE 2

On a glass tooling surface a sheet of Halar as obtained from Solvay Solexis (an ethylene chlorotrifluoroethylene (ECTFE)) of 100 μm was placed. On top of the sheet of Halar a sheet of a 49 grams/m² glass fibre pre-preg (MTM59/GF1200-50%RW) was placed. The thermoset polymer of the pre-preg had a glass transition temperature of >135° C. A SunPower A300 solar cell (the crystalline silicon photo-electricity device) was placed with its light sensitive side facing downwards. A next sheet of a 49 grams/m² glass fibre pre-preg (MTM59/GF1200-50% RW) was placed on top.

After placing a release film followed by a bleeder/breather and vacuum bag a vacuum was applied of 5 mbar and the laminate was allowed to de-air for 4 hours. Subsequently the temperature is raised to 100° C. and the laminate is cured for 4 hours. Subsequently the laminate is allowed to cool to room temperature. At room temperature the vacuum is released and the solar laminate is obtained having the dimensions of 12 by 12 cm of crystalline silicon photo-electricity device in a 14 by 14 cm laminate. The thickness of the laminate is between 300 and 600 μm.

The solar cell laminate as obtained was bended to 180°. The minimum radium R (FIG. 5) at which no breakage of the cell occurred was found to be 6 cm.

### EXAMPLE 3

On a glass tooling surface a release film was placed. On top of the release film a 49 grams/m2 glass fibre pre-preg (MTM59/GF1200-50% RW) was placed. The thermoset polymer of the pre-preg had a glass transition temperature of >135 ° C. A SunPower A300 solar cell (the crystalline silicon photo-electricity device) was placed with its light sensitive side facing downwards. A next sheet of a 49 grams/m² glass fibre pre-preg (MTM59/GF1200-50% RW) was placed on top.

After placing a release film followed by a bleeder/breather and vacuum bag a vacuum was applied of 5 mbar and the laminate was allowed to de-air for 4 hours. Subsequently the temperature is raised to 100° C. and the laminate is cured for 4 hours. Subsequently the laminate is allowed to cool to room temperature. At room temperature the vacuum is released and the solar laminate is obtained having the dimensions of 12 by 12 cm of crystalline silicon photo-electricity device in a 14 by 14 cm laminate. The thickness of the laminate is between 200 and 400 μm.

The solar cell laminate as obtained was bended to 180°. The minimum radium R (FIG. 5) at which no breakage of the cell occurred was found to be 6 cm.

### EXAMPLE 4

On a glass tooling surface a sheet of double sided treated Tefzel(r) ETFE (200 CLZ 20) as obtained from DuPont of 50 μm was placed. On top of the sheet of Tefzel a sheet of a 49 grams/m² glass fibre pre-preg (MTM59/GF1200-50% RW) was placed. The thermoset polymer of the pre-preg had a glass transition temperature of >135° C. A SunPower A300 solar cell (the crystalline silicon photo-electricity device) was placed with its light sensitive side facing downwards. A next sheet of a 49 grams/m² glass fibre pre-preg (MTM59/GF1200-50% RW) was placed on top.

After placing a release film followed by a bleeder/breather and vacuum bag a vacuum was applied of 5 mbar and the laminate was allowed to de-air for 4 hours. Subsequently the temperature is raised to 100° C. and the laminate is cured for 4 hours. Subsequently the laminate is allowed to cool to room temperature. At room temperature the vacuum is released and the solar laminate is obtained having the dimensions of 12 by 12 cm of crystalline silicon photo-electricity device in a 14 by 14 cm laminate. The thickness of the laminate is between 300 and 600 μm.

The laminate had excellent bending properties.

### EXAMPLE 5

On a glass tooling surface a sheet of single sided treated Tefzel(r) ETFE PV3221 (200 CLZ) as obtained from DuPont of 50 μm was placed. On top of the sheet of Tefzel a layer of EVA (VistaSolar Type 496.10) was placed. The encapsulated cell as obtained from example 3 was placed with its light sensitive side facing downwards. A next sheet of EVA (VistaSolar Type 496.10) was placed on top. On top of the second layer of EVA a layer of black Tedlar (PV2112) as obtained from DuPont was placed.

After placing a release film followed by a bleeder/breather and vacuum bag a vacuum was applied of 5 mbar. Subsequently the temperature is raised quickly (3° C./min) to 143° C. and the laminate is cured for 0.5 hours. Subsequently the laminate is allowed to cool to room temperature. At room temperature the vacuum is released and a weather resistant solar laminate is obtained having the dimensions of 12 by 12 cm of crystalline silicon photo-electricity device in a 16 by 16 cm laminate. The thickness of the laminate is between 900 and 1600 μm.

The laminate had excellent bending properties.

### EXAMPLE 6

Example 5 was repeated except that the cell as obtained in Example 4 was used instead of the cell of Example 3. The laminate had excellent bending properties.

### EXAMPLE 7

Example 3 was repeated except a 23 grams/m2 glass fibre pre-preg (Cycom®759F 70% A1100/23gsm glass fibre) was used instead of 49 grams/m2 glass fibre pre-preg (MTM59/GF1200-50% RW). The laminate had excellent bending properties.

### EXAMPLE 8

Example 1-4 were repeated except a Sunpower C60 solar cell was used instead of SunPower A300 solar cell (the crystalline silicon photo-electricity device). The laminate had excellent bending properties.

### COMPARATIVE EXPERIMENT A

Example 1 was repeated except that instead of the two layers of a 23 grams/m² glass fibre pre-preg two layers of EVA (VistaSolar Type 496.10) was used.

The solar laminate thus obtained was bended. Long before reaching a bend of 180° the cell broke. The ability to bend this cell was significantly worse as compared to the bending properties of the laminates of Examples 1-6.

### COMPARATIVE EXPERIMENT B

Example 1 was repeated except that instead of the two layers of a 23 grams/m² glass fibre pre-preg the front layer of glass was replaced by a layer of EVA (VistaSolar Type 496.10).

The solar laminate thus obtained was bended. Long before reaching a bend of 180° the cell broke, however it was possible to bend the laminate further then in comparative experiment A before the cell broke. The ability to bend this cell was significantly worse as compared to the bending properties of the laminates of Examples 1-6.

### EXAMPLE 9

Inside a glass tube with an outer diameter of 180 mm, an inner diameter of 170 mm and a length of 1000 mm a layer of EVA (VistaSolar Type 496.10) was placed. The encapsulated cell as obtained from example 3 was placed on top with its light sensitive side facing toward the glass tube. A next sheet of EVA (VistaSolar Type 496.10) was placed on top. On top of the next layer of EVA a layer of black backsheet (AAA SS 3554) as obtained from IsoVoltaic was placed. After placing a release film followed by a bleeder/breather and tubular vacuum bag (RELBAG460 70 mu-12″ obtained from Airtech), the tooling rings with four vacuum ports each were attached to the glass tube as shown in FIG. 9. Between the tooling rings and glass tube a silicon seal was present to guarantee an airtight connection. Inside the tooling rings a sealant (AT-200Y) as obtained from General Sealants Inc. was attached. The bleeder and vacuum bag were positioned over the four vacuum ports on the inside of the tooling rings, followed by attaching the tubular vacuum bag to the sealant. Then the blind flanges were attached to the tooling ring using a silicon seal in between. One of the blind flanges was provided with a vacuum port for connecting a vacuum pump to the inside of the tubular structure. Two vacuum pumps were attached to the structure to achieve a first and second vacuum; one pump to the rings which are connected to the space between vacuum bag and interior wall of the glass tube (to control the laminate pressure: Plam) and one pump to the flange, which is in contact with the centre space of the tube (to control the core pressure: Pcore). The whole setup was placed in an oven. Before turning on the oven the pressures Plam and Pcore were set to 40 mbar. Subsequently the temperature was raised at 3° C./min to 60° C. When a temperature of 60° C. was reached, the Pcore was lowered to 700 mbar, while Plam was kept constant at 40 mbar. The temperature was subsequently raised at 3° C./min to 143° and the laminate was cured at that temperature for 0.5 hours. Subsequently the temperature is reduced to room temperature. At room temperature the vacuum was released and a tubular solar laminate is obtained having the dimensions of 1000 mm by 180 mm diameter of crystalline silicon photo-electricity device. The thickness of the laminate including glass was between 6.3 mm and 6.6 mm.

### EXAMPLE 10

Inside a glass tube with an outer diameter of 180 mm, an inner diameter of 170 mm and a length of 300 mm a layer of EVA (VistaSolar Type 496.10) was placed. The encapsulated cell as obtained from example 7 was placed on top with its light sensitive side facing toward the glass tube. A next sheet of EVA (VistaSolar Type 496.10) was placed on top. On top of the next sheet of EVA a layer of white backsheet (APA WW 4004) as obtained from IsoVoltaic was placed. After placing a release film a bleeder/breather and a tubular vacuum bag (RELBAG460 70 mu-12″ obtained from Airtech) was applied. Subsequently tooling rings with four vacuum ports each were attached to the glass tube. Between the tooling rings and glass tube a silicon seal was present to guarantee an airtight connection. Inside the tooling rings a sealant (AT-200Y) as obtained from General Sealants Inc. was attached. The bleeder and vacuum bag were positioned over the four vacuum ports on the inside of the tooling rings, followed by attaching the tubular vacuum bag to the sealant. Then the blind flanges were attached to the tooling ring using a silicon seal in between. One of the blind flanges was provided with an opening to apply the second vacuum by means of a vacuum pump to the inside of the tubular tooling device (Pcore). A second vacuum pump was attached to the openings in the tooling rings to apply the first vacuum (Plam). The resulting tooling device was placed in an oven and the cure cycle was used wherein before turning on the oven the pressures Plam and Pcore were set to 10 mbar. Subsequently the temperature was raised at 5° C./min to 150° C. At a temperature of 60° C. the Pcore was lowered to 700 mbar, while Plam is kept constant at 10 mbar. When a temperature of 150° was reached, the laminate was cured for 0.25 hours at that temperature. Subsequently the laminate is allowed to cool to room temperature. At room temperature the vacuum was released and a glass covered tubular solar laminate was obtained having the dimensions of 300 mm by 180 mm diameter of crystalline silicon photo-electricity device. The thickness of the laminate including glass was between 6.3 mm and 6.6 mm.

1. A solar cell laminate comprising crystalline silicon photo-electricity device and comprising of the following layers:
(i) a first layer comprising of a woven or knit glass mat and a polymer,
(ii) a second layer comprising a crystalline silicon photo-electricity device, and
(iii) a third layer comprising of a woven or knit fibre mat and a polymer.

2. The solar cell laminate according to claim 1, wherein the polymer in the first and/or third layer is a thermoset polymer.

3. The solar cell laminate according to claim 2, wherein the thermoset polymer of the first layer (i) is a polyester, a polyurethane or an epoxy resin.

4. The solar cell laminate according to claim 3, wherein the thermoset polymer has a glass transition temperature of greater than 80° C.

5. The solar cell laminate according to claim 1, wherein a woven glass mat is part of the first layer and wherein the woven glass mat has a weight of between 10 and 200 grams/m².

6. The solar cell laminate according to claim 5, wherein the woven glass mat has a weight of between 20 and 80 grams/m².

7. The solar cell laminate according to claim 1, wherein the third layer comprises of a woven or knit glass fibre mat.

8. The solar cell laminate according to claim 1, wherein the laminate also comprises a cover layer comprised of a fluorocarbon-based polymer on top of the first layer.

9. (canceled)

10. (canceled)

11. A process to make a solar cell laminate wherein the solar cell laminate comprises of a cover layer comprised of a fluorocarbon-based polymer, a first layer comprising of a woven or knit glass mat and a polymer, a second layer comprising a crystalline silicon photo-electricity device, and a third layer comprising of a woven or knit glass mat and a polymer by
(a) placing a film of the fluorocarbon-based polymer on a support to create a cover layer,
(b) placing the first, second and third layer on top of the cover layer to obtain a layered intermediate,
(b) creating a vacuum around the layered intermediate,
(c) increasing the temperature of the layered intermediate to a temperature not exceeding the glass transition temperature by 50° C. of the polymer of the first layer,
(d) cooling the layered intermediate and
(e) releasing the vacuum to obtain the solar cell laminate.

12. The process according to claim 11, wherein the polymer in the first and/or third layer is a thermoset polymer.

13. The process according to claim 10, wherein the temperature of the layered intermediate is increased in step (c) to a temperature not exceeding the glass transition temperature by 50° C. of the thermoset polymer of the first and or third layer, whichever temperature is the lowest.

14. (canceled)

15. (canceled)

16. An object comprising a support and a solar laminate according to claim 1 wherein the laminate is present on a curved surface of the object.

17. The object according to claim 16, wherein the object is a roof tile.

18-38. (canceled)

39. The solar cell laminate according to claim 7, wherein a woven glass mat is part of the third layer and wherein the woven glass mat has a weight of between 10 and 200 grams/m2.

40. The process according to claim 11, wherein the thermoset polymer of the first layer and/or third layer is a polyester, a polyurethane or an epoxy resin.

41. The process according to claim 40, wherein the polymer has a glass transition temperature of greater than 80° C.

42. The process according to claim 11, wherein a woven glass mat is part of the first layer and wherein the woven glass mat has a weight of between 10 and 200 grams/m2.

43. The process according to claim 42, wherein the woven glass mat has a weight of between 20 and 80 grams/m2.

44. The process according to claim 11, wherein the third layer comprises of a woven or knit glass fibre mat.

45. The object according to claim 16, wherein the object is a tubular object comprising one or more solar laminates and having an outer layer of glass.
